(19) United States
(12) Patent Application Publication
(10) Pub. No.: US 2024/0152329 A1
(43) Pub. Date: May 9, 2024

(54) K-CLUSTER RESIDUE NUMBER SYSTEM FOR EDGE AI COMPUTING

(71) Applicant: Kneron Inc., San Diego, CA (US)

(72) Inventors: Oscar Ming Kin Law, San Diego, CA (US); Chun Chen Liu, San Diego, CA (US)

(73) Assignee: Kneron Inc., San Diego, CA (US)

(21) Appl. No.: 17/978,235

(22) Filed: Nov. 1, 2022

(51) Int. Cl. G06F 7/72; G06F 7/575

(52) U.S. Cl. CPC G06F 7/72; G06F 7/575

(57) ABSTRACT

A k-cluster residue number system has a processor and memory coupled to the processor. The processor is used to generate a modular set composed of P coprime integers, generate a dynamic range by taking a product of the P coprime integers, generate quotient indices for all integers in the dynamic range, generate row indices for all integers in the dynamic range, generate column indices for all integers in the dynamic range, and generate a look-up table according to the quotient indices, row indices, the column indices, and all integers in the dynamic range. P is an integer greater than 2, and the P coprime integers include 2. The memory is used to store the look-up table.

### BACKGROUND OF THE INVENTION

### 1. Field of the Invention

The present invention is related to a k-cluster residue number system, and more particularly, to a memory-based k-cluster residue number system capable of performing multiplicative scaling, overflow detection, and mixed sign iterative division.

### 2. Description of the Prior Art

Edge artificial intelligence (AI) computing is an area of rapid growth, which integrates neural networks with the Internet of Things (IoT) together for computer vision, natural language processing, and self-driving car applications, it quantizes the floating-point number to fixed-point integer for inference operations. In-memory architecture is one of the important Edge AI computing platforms, which stacks the memory over the top of the logic circuits for Memory Centric Neural Computing (MCNC). The data is directly loaded from stacked memory to Processing Elements (PEs) for computation, it avoids loading the data from the external memory and minimizes data transfer. It significantly reduces the latency and speeds up the operations. The performance is further enhanced using Residue Number System (RNS), which fully utilizes the internal memory to store the data for integer operations.

Residue Number System (RNS) is a number system, which first defines the moduli set and transforms the numbers to their integer remainders (also called residue) through modulo division, then performs the arithmetic operations (addition and multiplication) on the remainders only. For example, the moduli set is defined as (7, 8, 9) with the numbers 13 and 17. The dynamic range is defined by the product of the moduli set with the range 504. It first transforms the numbers to their residue through the modulo operations 13→(6, 5, 4) and 17→(3, 1, 8), then performs addition and multiplication on residues only, (6, 5, 4)+(3, 1, 8)=(9, 6, 12)→(2, 6, 3), which is equal to 30. (6, 5, 4)*(3, 1, 8)=(18, 5, 32)→(4, 5, 5), which is equal to 221. Since the remainder magnitude is much smaller, it only requires simple logic for parallel computations. The drawback of RNS is sign detection, magnitude comparison, and division support. The residues are required to convert back to the binary number domain for those operations.

To improve the Edge AI computing performance, it first performs the floating-point to integer quantization, which converts the trained neural network model to the integer one. It simplifies the design and operations and provides an energy-efficient solution. The k-Cluster Residue Number System (k-RNS) is proposed to enhance neural network inference through parallel distributive computation. It breaks down the integers to their remainders (residues) with different moduli sets, then performs the addition, subtraction, and multiplication on the remainders only. The k-RNS resolves the conventional RNS issues, sign detection, magnitude comparison, and division. It also scales the convolution product, then, no additional moduli sets are required to increase the dynamic range. It can also detect the integer overflow and adjust the summation of convolution products. Finally, the optimal division is proposed to further enhance the k-RNS operations. Therefore, K-Cluster Residue Number System (k-RNS) becomes useful for Edge AI computing.

### SUMMARY OF THE INVENTION

In an embodiment, a k-cluster residue number system comprises a processor and memory coupled to the processor. The processor is configured to generate a modular set composed of P coprime integers, generate a dynamic range by taking a product of the P coprime integers, generate quotient indices for all integers in the dynamic range, generate row indices for all integers in the dynamic range, generate column indices for all integers in the dynamic range, and generate a look-up table according to the quotient indices, row indices, the column indices, and all integers in the dynamic range. P is an integer greater than 2, and the P coprime integers include 2. The memory is configured to store the look-up table.

In another embodiment, a method for generating a k-cluster residue number system comprises generating a modular set composed of P coprime integers, generating a dynamic range by taking a product of the P coprime integers, generating quotient indices for all integers in the dynamic range, generating row indices for all integers in the dynamic range, generating column indices for all integers in the dynamic range, generating a look-up table according to the quotient indices, row indices, the column indices, and all integers in the dynamic range, and storing the look-up table in a memory of the k-cluster residue number system. P is an integer greater than 2, and the P coprime integers include 2. The memory is configured to store the look-up table.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIG. 1 shows a k-cluster residue number system (k-RNS) according to an embodiment of the present invention.

FIG. 2 shows the look-up table in FIG. 1.

FIG. 3 shows the multiplication scaling circuit of the processor in FIG. 1.

FIG. 4 shows the overflow detection circuit of the processor in FIG. 1.

FIG. 5 shows the division circuit of the processor in FIG. 1.

### DETAILED DESCRIPTION

To represent an n-bit integer and it's negative using a k-cluster residue number system (k-RNS), it first defines a modular set of p coprime integers as m₁, . . . , 2, . . . , mₚ) where a dynamic range is generated according to the product of the modular set (m₁, . . . , 2, . . . , mₚ). When a modular set of 3 coprime integers is chosen to be (2^{n/2}−1, 2, 2^{n/2}+1), the dynamic range is set to [−(2ⁿ−1), (2ⁿ−2)]. The modular set is not limited to 3 coprime integers, the number of coprime integers in the modular set can be increased to increase the dynamic range and keep the moduli small. In this case, the k-RNS converts each integer in the dynamic range to its row indices and column index formed by remainders through modulo division such as Equations (1) and (2).

rᵢ=I mod mi, when I is a positive integer (1)

rᵢ=(M−I) mod mi, when I is a negative integer (2)
where:
rᵢ is a row index or a column index;

I is an integer in the dynamic range;

M is the number of integers in the dynamic range; and mᵢ is a coprime integer of the modular set.

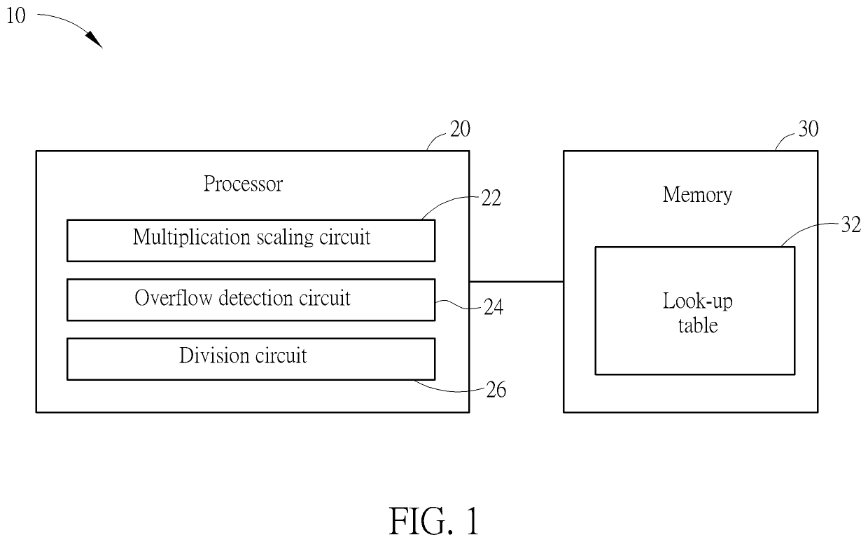

FIG. 1 shows a k-cluster residue number system (k-RNS) 10 according to an embodiment of the present invention. The k-cluster residue number system 10 may comprise a processor 20, and a memory 30 coupled to the processor 20. The processor 20 is used to generate the modular set composed of p coprime integers, generate the dynamic range by taking a product of the p coprime integers, generate quotient indices for all integers in the dynamic range, generate row indices for all integers in the dynamic range, generate column indices for all integers in the dynamic range, and generate a look-up table 32 according to the row indices, the column indices and all integers in the dynamic range. One of the p coprime integers is 2. Memory 30 is used to store the look-up table 32. The processor 20 may comprise a multiplication scaling circuit 22, an overflow detection circuit 24, and a division circuit 26.

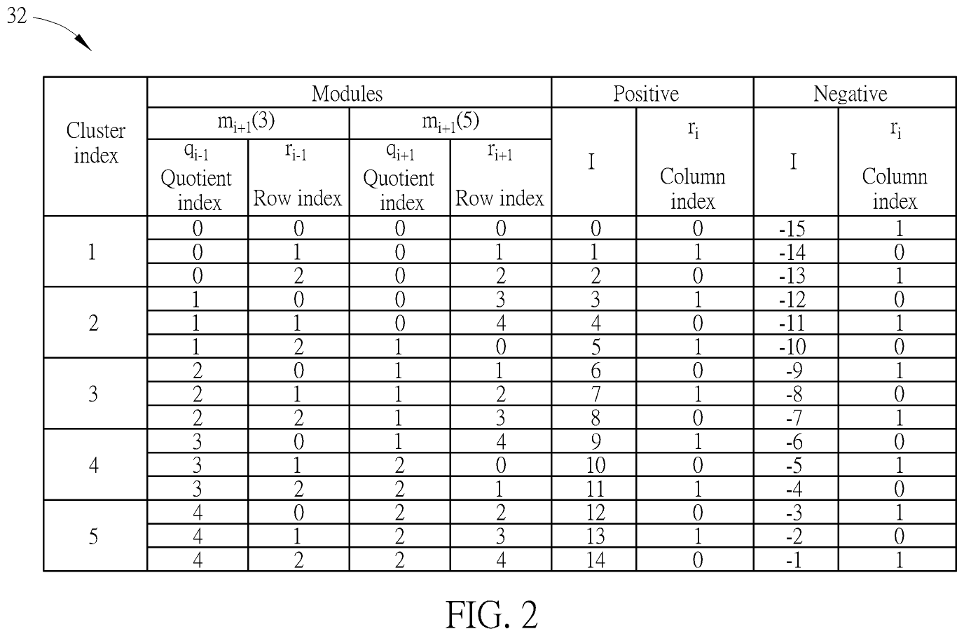

FIG. 2 shows the look-up table 32. The look-up table 32 can be exemplified by a 4-bit (n=4) integer. The modular set (m₁, m₂, m₃) of 3 integers can be chosen as (2^{n/2}−1, 2, 2^{n/2}+1)=(2^{4/2}−1, 2, 2^{4/2}+1)=(3,2,5) to represent the 4-bit integer and its negative. In this modular set, the first element m₁, and third element m₃ are moduli of row indices, and the second element m₂ is the modulus of the column index. The dynamic range is [−(2⁴−1), (2⁴−2)]=[−15,14]. That is, the dynamic range includes integers from −15 to 14. The modular set (3,2,5) is used throughout different embodiments of the detailed description for illustrative purposes, not for limiting the scope of the embodiments.

The look-up table 8 may include 9 columns: cluster index, quotient index qᵢ₋₁ of modulus mᵢ₋₁ (i.e., a quotient index of modulus 3), index rᵢ₋₁ of the modulus mᵢ₋₁, quotient index qᵢ₊₁ of modulus mᵢ₊₁ (i.e., a quotient index of modulus 5), positive integer column, column index rᵢ of the positive integer, negative integer column, and column index rᵢ of the negative integer. In this example, since the modular set has 3 coprime integers, each integer has 2 quotient indices, 2 row indices, and a column index. The positive integer column may list positive integers from 0 to 14 in ascending order. The negative integer column may list negative integers from −15 to −1 in ascending order. The integers are grouped according to the first row index modulo behavior. The integers 0 to 2, and −15 to −13 may be grouped to cluster 1. The integers 3 to 5, and −12 to −10 may be grouped to cluster 2. The integers 6 to 8, and −9 to −7 may be grouped to cluster 3. The integers 9 to 11, and −6 to −4 may be grouped to cluster 4. The integers 12 to 14, and −3 to −1 maybe grouped to cluster 5. This grouping approach is only for an illustrative purpose, not for limiting the scope of the embodiment.

The processor 20 converts 0 to (0,0,0) through dividing (3,2,5), the coprime integers of the modular set, since (0,0,0) are remainders of 0 over (3,2,5); and converts −15 to (0,1,0) through dividing (3,2,5) since (0,1,0) are remainders of −15 over (3,2,5). The processor 20 converts 1 to (1,1,1) through dividing (3,2,5) since (1,1,1) are remainders of 1 over (3,2,5) and converts −14 to (1,0,1) through dividing (3,2,5) since (1,0,1) are remainders of −14 over (3,2,5). The processor 20 converts 2 to (2,0,2) through dividing (3,2,5) since (2,0,2) are remainders of 2 over (3,2,5) and converts −13 to (2,1,2) through dividing (3,2,5) since (2,1,2) are remainders of −13 over (3,2,5). The same approach can be applied to other numbers and is thus not elaborated herein.

Because 0 and −15 have the same row numbers (0,0), 0 and −15 are listed in the same row. Their difference is that 0 has a column number of 0, and −15 has a column number of 1. Because 1 and −14 have the same row numbers (1,1), 1 and −14 are listed in the same row. Their difference is that 1 has a column number of 1, and −14 has a column number of 0. Because 2 and −13 have the same row numbers (2,2), 2 and −13 are listed in the same row. Their difference is that 2 has a column number of 0, and −13 has a column number of 1.

The quotient is equal to the quotient index qᵢ₋₁ when the integer I is divided by the modulus mᵢ₋₁, and the quotient is equal to the quotient index qᵢ₊₁ when the integer is divided by the modulus mᵢ₊₁. In the embodiment, since the modular set (m₁, m₂, m₃) is chosen as (2^{n/2}−1, 2, 2^{n/2}+1)=(2^{4/2}−1, 2, 2^{4/2}+1)=(3,2,5), the quotient is equal to the quotient index qᵢ₋₁ when the integer is divided by 3, and the quotient is equal to the quotient index qᵢ₊₁ when the integer is divided by 5.

For Edge AI computing, the processor 20 converts the floating-point number to a fixed-point integer through quantization. Assume the quantization is symmetrical, the floating-point number is defined between [−α, α] and its fixed-point integer x_{q} is quantized in the range [−α_{q}, α_{q}].

$${x}_{q} = round ( \frac{1}{S} x ) \qquad ( 3 )$$

$$S = \frac{α}{{α}_{q}} \qquad ( 4 )$$

$$x ≅ {Sx}_{q} \qquad ( 5 )$$

$$Y = XW + b \qquad ( 6 )$$

$${y}_{ij} = {\sum }_{k = 1}^{n} {x}_{ik} {w}_{kj} + {b}_{j} \qquad ( 7 )$$

### Convolution

### Floating-Point to Integer Conversion

$$\begin{matrix}{s}_{y} {y}_{qij} = {\sum }_{k = 1}^{n} {s}_{x} {x}_{qik} {s}_{w} {w}_{qkj} + {s}_{b} {b}_{qj} & ( 8 ) \\ \frac{{α}_{y}}{{α}_{q}} {y}_{qij} = {\sum }_{k = 1}^{n} \frac{{α}_{x} {α}_{w}}{{α}_{q} {α}_{q}} {x}_{qik} {w}_{qkj} + \frac{{α}_{b}}{{α}_{q}} {b}_{qj} & ( 9 ) \\ \frac{{α}_{y}}{{α}_{x} {α}_{w}} {y}_{qij} = {\sum }_{k = 1}^{n} \frac{{x}_{qik} {w}_{qkj}}{{α}_{q}} + \frac{{α}_{b}}{{α}_{x} {α}_{w}} & ( 10 )\end{matrix}$$

To avoid the integer overflow, multiplicative scaling is used to scale down the convolution product. It first represents two integers w and x in terms of the moduli set shown in FIG. 2. Then, the product is scaled down by the scaling factor α_{q} using equation (10) where the scaling factor is defined as the product of the moduli set (i.e., α_{q}=mᵢ₋₁mᵢ₊₁). For multiple moduli sets (m1, . . . , mp), the scaling factor is also defined as α_{q}Σ₁^{p}mᵢ/2

$$\begin{matrix}x = {q}_{i - 1} {m}_{i - 1} + {r}_{i - 1} & ( 11 ) \\ w = {q}_{i + 1} {m}_{i + 1} + {r}_{i + 1} & ( 12 ) \\ xw = {q}_{i - 1} {q}_{i + 1} {m}_{i - 1} {m}_{i + 1} + {q}_{i - 1} {m}_{i - 1} {r}_{m - 1} + {q}_{i + 1} {m}_{i + 1} {r}_{i + 1} + {r}_{i - 1} {r}_{i + 1} & ( 13 )\end{matrix}$$

$$\frac{xw}{{m}_{i - 1} {m}_{i + 1}} = \frac{1}{{m}_{i - 1} {m}_{i + 1}} ( {q}_{i - 1} {q}_{i + 1} {m}_{i - 1} {m}_{i + 1} + {q}_{i - 1} {m}_{i - 1} {r}_{i - 1} + {q}_{i + 1} {m}_{i + 1} {r}_{i + 1} + {r}_{i - 1} {r}_{i + 1} ) \qquad ( 14 )$$

$$\begin{matrix}\frac{xw}{{m}_{i - 1} {m}_{i + 1}} = {q}_{i - 1} {q}_{i + 1} + \frac{{q}_{i - 1} {r}_{i + 1}}{{m}_{i + 1}} + \frac{{q}_{i + 1} {r}_{i - 1}}{{m}_{i - 1}} + \frac{{r}_{i - 1} {r}_{i + 1}}{{m}_{i - 1} {m}_{i + 1}} & ( 15 ) \\ \frac{xw}{{m}_{i - 1} {m}_{i + 1}} = {q}_{i - 1} {q}_{i + 1} + ⌈ \frac{{q}_{i - 1} {r}_{i + 1}}{{m}_{i + 1}} + \frac{{q}_{i + 1} {r}_{i - 1}}{{m}_{i - 1}} ⌉ & ( 16 )\end{matrix}$$

where
mᵢ₋₁ and mᵢ₊₁ are two coprime integers of the modular set;
qᵢ₋₁ is a quotient index of the quotient indices when the integer x is divided by mᵢ₋₁;
rᵢ₋₁ is a row index of the row indices when the integer x is divided by mᵢ₋₁;
qᵢ₊₁ is a quotient index of the quotient indices when the integer w is divided by mᵢ₊₁;
rᵢ₊₁ is a row index of the row indices when the integer w is divided by mᵢ₊₁ and
┌┐ is a rounding function.

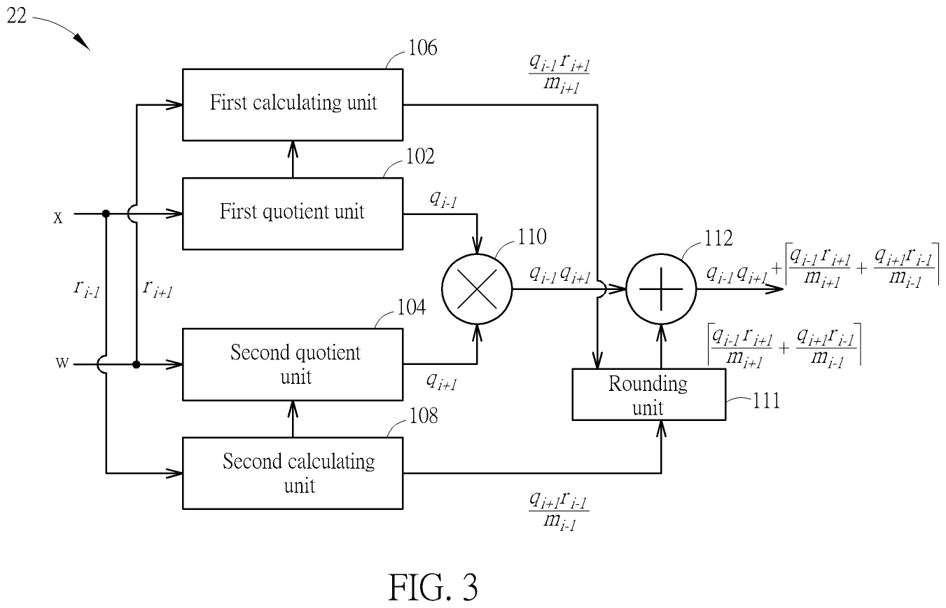

The multiplication scaling circuit 22 of processor 20 is illustrated in FIG. 3. The multiplication scaling circuit 22 comprises a first quotient unit 102, a second quotient unit 104, a first calculating unit 106, a second calculating unit 108, a multiplier 110, a rounding unit 111, and an adder 112. The first quotient unit 102 is configured to output the quotient index qᵢ₋₁ according to the integer x. The second quotient unit 104 is configured to output the quotient index qᵢ₊₁ according to the integer w. The first calculating unit 106 is configured to output a value of

$$\frac{{q}_{i - 1} {r}_{i + 1}}{{m}_{i + 1}}$$

according to the quotient index qᵢ₋₁ and the row index rᵢ₊₁. The second calculating unit 108 is configured to output a value of

$$\frac{{q}_{i + 1} {r}_{i - 1}}{{m}_{i - 1}}$$

according to the quotient index qᵢ₊₁ and the row index rᵢ₋₁. The multiplier 110 has a first input coupled to an output of the first quotient unit for receiving the quotient index qᵢ₊₁, a second input coupled to an output of the second quotient unit for receiving the quotient index qᵢ₊₁, and an output for outputting a product of the quotient index qᵢ₋₁ and the quotient index qᵢ₊₁. The rounding unit 111 has a first input coupled to an output of the first calculating unit 106 for receiving the value of

$$\frac{{q}_{i - 1} {r}_{i + 1}}{{m}_{i + 1}} ,$$

a second input coupled to an output of the second calculating unit 108 for receiving the value of

$$\frac{{q}_{i - 1} {r}_{i + 1}}{{m}_{i + 1}} ,$$

and an output for outputting the value of

$$⌈ \frac{{q}_{i - 1} {r}_{i + 1}}{{m}_{i + 1}} + \frac{{q}_{i + 1} {r}_{i - 1}}{{m}_{i - 1}} ⌉ .$$

The adder 112 has a first input coupled to the output of the rounding unit 111 for receiving the value of

$$⌈ \frac{{q}_{i - 1} {r}_{i + 1}}{{m}_{i + 1}} + \frac{{q}_{i + 1} {r}_{i - 1}}{{m}_{i - 1}} ⌉ ,$$

a second input coupled to an output of the multiplier 110 for receiving the product of the quotient index qᵢ₋₁ and the quotient index qᵢ₊₁, and an output for outputting a sum of the value of

$$⌈ \frac{{q}_{i - 1} {r}_{i + 1}}{{m}_{i + 1}} + \frac{{q}_{i + 1} {r}_{i - 1}}{{m}_{i - 1}} ⌉$$

and the product of the quotient index qᵢ₋₁ and the quotient index qᵢ₊₁. This approach is not only applied for the scaling, the factor

$$\frac{xw}{{m}_{i - 1} {m}_{i + 1}}$$

is used to record the multiplication overflow. The multiplication scaling circuit 22 may perform multiplication overflow correction according to the value of the factor

$$\frac{xw}{{m}_{i - 1} {m}_{i + 1}} .$$

If the factor

$$\frac{xw}{{m}_{i - 1} {m}_{i + 1}}$$

is odd, the residue rᵢ should be interchanged 0<->1; otherwise, the residue rᵢ is unchanged if the factor

$$\frac{xw}{{m}_{i - 1} {m}_{i + 1}}$$

is even.

To illustrate the multiplication scaling, two integers 13 and 11 are multiplied by each other and divided by the scaling factor 15 to generate a result as

$$⌈ \frac{13 \times 11}{15} ⌉ = ⌈ \frac{143}{15} ⌉ = 9.$$

With the multiplication scaling, 13 and 11 are represented as 13=(4×3+1) and 11=(2×5+1), then the processor 20 divides the product with the scaling factor,

$$( 13 \times 11 ) / 15 = 4 \times 2 + ⌈ \frac{4 \times 1}{5} + \frac{2 \times 1}{3} ⌉ = 8 + 1 = 9.$$

The rounding operations can be realized using following k-RNS multiplicative scaling rounding look-up table 1 and table 2. Similarly, the negative multiplication scaling first converts the integer to be positive and performs the multiplication scaling. The result is adjusted through the sign change.

TABLE 1
k-RNS Multiplicative Scaling Rounding Look-up Table (Moduli 3)

| | | qᵢ₊₁ | | |
|---|---|---|---|---|
| | | 0 | 1 | 2 |
| rᵢ₋₁ | 0 | 0 | 0 | 0 |
| | 1 | 0 | 0 | 1 |
| | 2 | 0 | 1 | 1 |

TABLE 2
k-RNS Multiplicative Scaling Rounding Look-up Table (Moduli 5)

| | | qᵢ₋₁ | | | | |
|---|---|---|---|---|---|---|
| | | 0 | 1 | 2 | 3 | 4 |
| rᵢ₊₁ | 0 | 0 | 0 | 0 | 0 | 0 |
| | 1 | 0 | 0 | 0 | 1 | 1 |
| | 2 | 0 | 0 | 1 | 1 | 2 |
| | 3 | 0 | 1 | 1 | 2 | 2 |
| | 4 | 0 | 1 | 2 | 2 | 3 |

The k-RNS 10 can also detect the integer overflow due to the summation of the convolution products. It fully utilizes the k-RNS periodic behavior to detect the overflow, and the overflow only occurs when both integers have the same sign (either both augend and addend are positive or negative). The integer overflow can be corrected by switching the residue rᵢ from 0 to 1 or from 1 to 0 with the dynamic range [−(2ⁿ−1), (2ⁿ−2)]. Assume two positive integers 11→(2,1,1) and 14→(2,0,4) are added together, the result becomes (1,1,0)→−5. The sign of the augend/addend and the sign of the sum are different, it shows the integer overflows. The result is corrected as (1,0,0)→10. It is consistent with the calculation 11+14=25=10+15 with a range [0,14]. Similarly, two negative integers −11→(1,1,4) and −14→(1,0,1) will generate a sum (2,1,0)→5 with a positive sign, the sum (2,1,0)→5 is adjusted to be (2,0,0)→−10. It is consistent with the calculation −11−14=−25=−15−10 with a range [−15,−1].

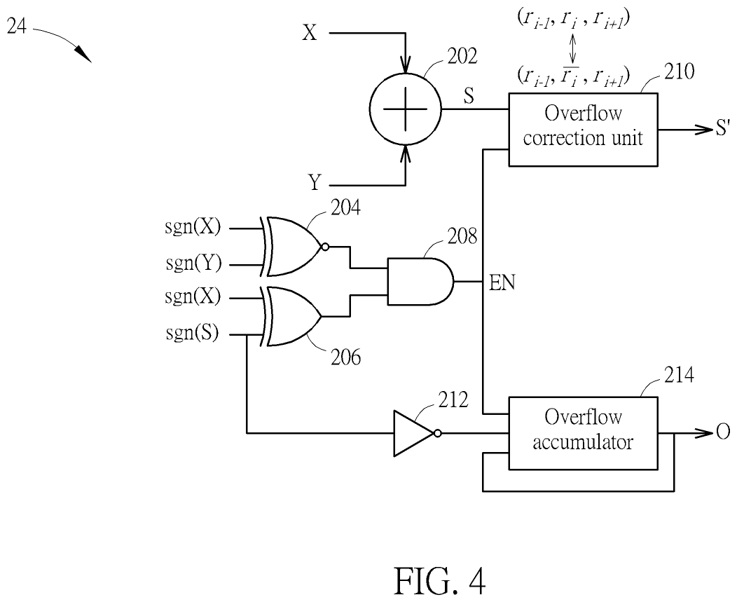

The overflow detection circuit 24 of processor 20 is illustrated in FIG. 4. The overflow detection circuit 24 is configured to detect overflow when processor 20 adds two integers X and Y. The overflow detection circuit 24 comprises an adder 202, an XNOR gate 204, an XOR gate 206, an AND gate 208, an overflow correction unit 210, an inverter 212, and an overflow accumulator 214. The adder 202 has two inputs for receiving the two integers X and Y, and an output for outputting a sum S of the two integers X and Y. The XNOR gate 204 has two inputs for receiving a sign sgn(x) of the integer X and a sign sgn(Y) of the integer Y. The XOR gate 206 has two inputs for receiving the sign sgn(x) of the integer X and a sign sgn(S) of the sum S of the two integers X and Y. The AND gate 208 has a first input coupled to an output of the XNOR gate 204, a second input coupled to an output of the XOR gate 206, and an output for outputting an enable signal EN. The overflow correction unit 210 is used to change the sign of the sum S of the two integers X and Y (i.e., switch the residue rᵢ from 0 to 1 or from 1 to 0) when the enable signal EN has a predetermined value (e.g., logic 1 or 0), so as to output an updated sum S′. The inverter 212 has an input for receiving the sign sgn(S) of the sum S of the two integers X and Y. The overflow accumulator 214 has a first input for receiving the enable signal EN, a second input coupled to an output of the inverter 212, and a third input coupled to an output of the overflow accumulator 214. The overflow accumulator 214 accumulates the number of times the overflow correction unit 210 changes the sign of the sum S of the two integers X and Y. In an embodiment of the present invention, processor 20 corrects a final convolution result according to the signal O outputted from the overflow accumulator 214.

For the k-RNS division, processor 20 first constructs the following quotient factor lookup table 3, which is defined by the minimum value in the dividend cluster and the maximum value in the divisor cluster.

TABLE 3
k-RNS Quotient Factor Lookup Table

| | | Dividend Cluster Index | | | | |
|---|---|---|---|---|---|---|
| | | 1 | 2 | 3 | 4 | 5 |
| Divisor | 1 | 1 | 1 | 3 | 4 | 6 |
| Cluster | 2 | 0 | 1 | 1 | 1 | 2 |
| Index | 3 | 0 | 0 | 1 | 1 | 2 |
| | 4 | 0 | 0 | 0 | 1 | 1 |
| | 5 | 0 | 0 | 0 | 0 | 1 |

Assign X₀=X and Q₀=0, then, the division circuit 26 of the processor 20 performs the iterative subtraction:

Division Q=X/Y (17)

Initialize divided X₀=X (18)

Initialize quotient Q₀=0 (19)

Iterative subtraction Xᵢ₊₁=Xᵢ−qᵢY (20)

where

X is the dividend;

Y is the divisor;

X₀ is the initialized divided;

Q₀ is the initialized quotient;
qᵢ is a quotient factor;

Xᵢ is a temporary dividend during the iterative division; and

Xᵢ₊₁ is an updated dividend.

To support the signed division, it first determines the signs of the dividend X and divisor Y, then converts the mixed sign division into the positive one and performs the iterative division. It finally converts the quotient and its remainder according to the following k-RNS Quotient/Remainder Conversion Table 4 using the signs of the dividend X and divisor Y to simplify the design.

TABLE 4
k-RNS Quotient/Remainder Conversion Table

Dividend

| | | + | − |
|---|---|---|---|
| Divisor | + | Quotient, + | Quotient, − |
| | | Remainder, + | Remainder, − |
| | − | Quotient, − | Quotient, + |
| | | Remainder, + | Remainder, − |

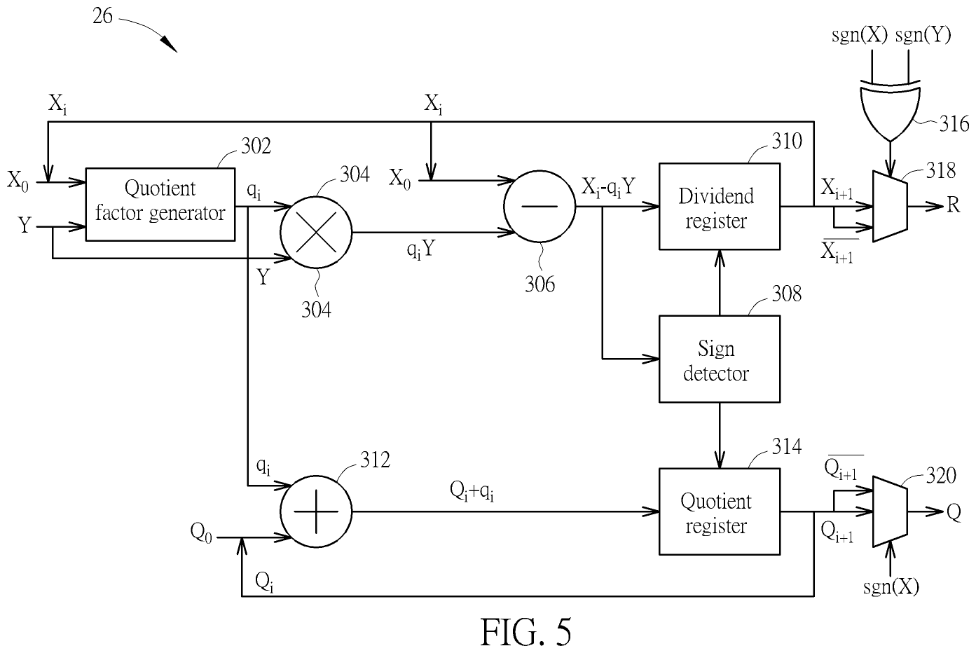

The division circuit 26 of the processor 20 is illustrated in FIG. 5. The division circuit 26 comprises a quotient factor generator 302, a multiplier 304, a subtractor 306, a sign detector 308, a dividend register 310, an adder 312, a quotient register 314, an XOR gate 316, a first multiplexer 318, and a second multiplexer 320. The quotient factor generator 302 has a first input for receiving a dividend (i.e., the initialized divided X₀ or the temporary dividend Xᵢ), a second input for receiving a divisor Y, and an output for outputting a quotient factor qᵢ according to a cluster index of the dividend X and a cluster index of the divisor Y. The multiplier 304 has a first input coupled to the output of the quotient factor generator 302 for receiving the quotient factor qᵢ, a second input for receiving the divisor Y, and an output for outputting a product qᵢY of the quotient factor qᵢ and the divisor Y. The subtractor 306 has a first input for receiving the dividend (i.e., the initialized divided X₀ or the temporary dividend Xᵢ), a second input for receiving the product qᵢY of the quotient factor qᵢ and the divisor Y, and an output for outputting a difference (Xᵢ−qᵢY) between the dividend Xᵢ and the product qᵢY of the quotient factor qᵢ and the divisor Y. The sign detector 308 has an input coupled to the output of the subtractor 306 for receiving the difference (Xᵢ−qᵢY). The dividend register 310 has a first input coupled to the output of the subtractor 306 for receiving the difference (Xᵢ−qᵢY), a second input coupled to a first output of the sign detector 308 for receiving a sign of the difference (Xᵢ−qᵢY), and an output for outputting the difference (Xᵢ−qᵢY) as an updated dividend Xᵢ₊₁ if the difference (Xᵢ−qᵢY) is zero or a positive integer. The adder 312 has a first input coupled to the output of the quotient factor generator 302 for receiving the quotient factor qᵢ, a second input for receiving a temporary quotient Qᵢ, and an output for outputting a sum (Qᵢ+qᵢ) of the quotient factor qᵢ and the temporary quotient Qᵢ. The quotient register 314 has a first input coupled to the output of the adder 312 for receiving the sum (Qᵢ+qᵢ) of the quotient factor qᵢ and the temporary quotient Qᵢ as an updated temporary quotient Qᵢ₊₁, a second input coupled to a second output of the sign detector 308 for receiving the sign of the difference (Xᵢ−qᵢY), and an output coupled to the adder 312 and the second multiplexer 320 for outputting the updated temporary quotient Qᵢ₊₁ if the sign of the difference (Xᵢ−qᵢY) is zero or positive. The XOR gate 316 has two inputs for receiving a sign sgn (X) of the dividend X and a sign sgn(Y) of the divisor Y. The first multiplexer 318 has two inputs coupled to the dividend register 310 for receiving the updated dividend Xᵢ₊₁ and an updated dividend bar X̅ᵢ̅₊̅₁̅, and a select terminal coupled to an output of the XOR gate 316. The first multiplexer 318 selectively outputs one of the updated dividend Xᵢ₊₁ and the updated dividend bar X̅ᵢ̅₊̅₁̅ as the remainder R according to a signal outputted from the XOR gate 316. The second multiplexer 320 has two inputs coupled to the quotient register 314 for receiving the updated temporary quotient Qᵢ₊₁ and an updated temporary quotient bar Q̅ᵢ̅₊̅₁̅, and a select terminal for receiving the sign sgn (X) of the dividend X. The second multiplexer 320 selectively outputs one of the updated temporary quotient Qᵢ₊₁ and the updated temporary quotient bar Q̅ᵢ̅₊̅₁̅ as the quotient Q according to the sign sgn (X) of the dividend X.

To illustrate the iterative division using iterative subtraction, assume the dividend X is 14→(2,0,4) and the divisor Y is 2→(2,0,2). X₀ is set to (2,0,4) (equation 18) and Q₀ is initialized to zero (0,0,0) (equation 6). Based on the dividend cluster index #5 and the divisor cluster index #1, the quotient factor q₀ is set to 6→(0,0,1) using Table 3. X′=(2,0,4)−(0,0,1)×(2,0,2)=(2,0,2) (equation 19). Since the result (2,0,2) is positive, it updates both Xᵢ and Q₁ where X1=X′=(2,0,2) and Q₁=(0,0,0)+(0,0,1)=(0,0,1) (equation 20). It continues the iteration, the cluster index of X1 is updated to #1 and q₁ is set to 1→(1,0,1), then X′=(2,0,2)−(1,0,1)×(2,0,2)=(0,0,0). The result is zero and the iteration is terminated. The final quotient is updated, Q2=(0,0,1)+(1,1,1)=(1,1,2)→7 and the remainder is set to zero. X2=X′=(0,0,0)→0. The result is consistent with the calculation 14/2=7 with zero remainder.

For negative division, the dividend X is set to −14→(1,0,1) and the divisor Y is kept at 2→(2,0,2), then the processor 20 converts the dividend X into positive and performs the iterative division with quotient Q=(1,1,2)→7 and the remainder R=(0,0,0)→0. Based on Table 4, the quotient is changed to −7 and the remainder is set to zero, it matches the calculation where −14/2=−7. Compare with the conventional RNS division, the k-RNS division of the present invention offers a better solution, it not only supports the mixed sign integer division with the same logic implementation but also reduces the number of iterations from 7 to 2. It simplifies the overall logic design and significantly speeds up the operations.

The k-RNS 10 of the present invention may perform multiplicative scaling to eliminate additional moduli set for overflow protection and simplify the scaling using the lookup table approach. The k-RNS 10 may also detect integer overflow to correct the results after overflow and record the overflow cycles for computation (i.e., scaling, normalization, etc.). The k-RNS 10 may perform mixed sign iterative division to reuse the positive iterative division to simplify mixed sign division and correct the signs of quotient and remainder after division.

Those skilled in the art will readily observe that numerous modifications and alterations of the device and method may be made while retaining the teachings of the invention. Accordingly, the above disclosure should be construed as limited only by the metes and bounds of the appended claims.

What is claimed is:

1. A k-cluster residue number system comprising:
a processor configured to:
generate a modular set composed of P coprime integers, wherein P is an integer greater than 2, and the P coprime integers include 2;
generate a dynamic range by taking a product of the P coprime integers;
generate quotient indices for all integers in the dynamic range;
generate row indices for all integers in the dynamic range;
generate column indices for all integers in the dynamic range; and
generate a look-up table according to the quotient indices, row indices, column indices, and all integers in the dynamic range; and
a memory coupled to the processor and configured to store the look-up table.

2. The k-cluster residue number system of claim 1, wherein the processor is further configured to multiply two integers x and w by using the look-up table according to a following equation:
$$\frac{xw}{{m}_{i - 1} {m}_{i + 1}} = {q}_{i - 1} {q}_{i + 1} + ⌈ \frac{{q}_{i - 1} {r}_{i + 1}}{{m}_{i + 1}} + \frac{{q}_{i + 1} {r}_{i - 1}}{{m}_{i - 1}} ⌉$$
where:
mᵢ₋₁ and mᵢ₊₁ are two coprime integers of the modular set;
qᵢ₋₁ is a quotient index of the quotient indices when the integer x is divided by mᵢ₋₁;
rᵢ₋₁ is a row index of the row indices when the integer x is divided by mᵢ₋₁;
qᵢ₊₁ is a quotient index of the quotient indices when the integer w is divided by mᵢ₊₁;
rᵢ₊₁ is a row index of the row indices when the integer w is divided by mᵢ₊₁; and
┌┐ is a rounding function.

3. The k-cluster residue number system of claim 2, wherein the processor comprises a multiplication scaling circuit comprising:
a first quotient unit configured to output the quotient index qᵢ₋₁ according to the integer x;
a second quotient unit configured to output the quotient index qᵢ₊₁ according to the integer w;
a first calculating unit configured to output a value of
$$\frac{{q}_{i - 1} {r}_{i + 1}}{{m}_{i + 1}}$$
according to the quotient index qᵢ₋₁ and the row index rᵢ₊₁;
a second calculating unit configured to output a value of
$$\frac{{q}_{i + 1} {r}_{i - 1}}{{m}_{i - 1}}$$
according to the quotient index qᵢ₊₁ and the row index rᵢ₋₁;
a multiplier having a first input coupled to an output of the first quotient unit for receiving the quotient index qᵢ₋₁ a second input coupled to an output of the second quotient unit for receiving the quotient index qᵢ₊₁ and an output for outputting a product of the quotient index qᵢ₋₁ and the quotient index qᵢ₊₁;
a rounding unit having a first input coupled to an output of the first calculating unit for receiving the value of
$$\frac{{q}_{i - 1} {r}_{i + 1}}{{m}_{i + 1}} ,$$
second input coupled with an output of the second calculating unit for receiving the value of
$$\frac{{q}_{i - 1} {r}_{i + 1}}{{m}_{i + 1}} ,$$
and an output for outputting the value of
$$⌈ \frac{{q}_{i - 1} {r}_{i + 1}}{{m}_{i + 1}} + \frac{{q}_{i + 1} {r}_{i - 1}}{{m}_{i - 1}} ⌉ ;$$
and
an adder having a first input coupled to an output of the rounding unit for receiving the value of
$$⌈ \frac{{q}_{i - 1} {r}_{i + 1}}{{m}_{i + 1}} + \frac{{q}_{i + 1} {r}_{i - 1}}{{m}_{i - 1}} ⌉ ,$$
a second input coupled to an output of the multiplier for receiving the product of the quotient index qᵢ₋₁ and the quotient index qᵢ₊₁ and an output for outputting a sum of the value of
$$⌈ \frac{{q}_{i - 1} {r}_{i + 1}}{{m}_{i + 1}} + \frac{{q}_{i + 1} {r}_{i - 1}}{{m}_{i - 1}} ⌉$$
and the product of the quotient index qᵢ₋₁ and the quotient index qᵢ₊₁.

4. The k-cluster residue number system of claim 3, wherein the multiplication scaling circuit performs multiplication overflow correction according to a value of
$$\frac{xw}{{m}_{i - 1} {m}_{i + 1}} .$$

5. The k-cluster residue number system of claim 4, wherein when the value of
$$\frac{xw}{{m}_{i - 1} {m}_{i + 1}}$$
is odd, a value of a residue rᵢ is changed; and
Wherein when the value of
$$\frac{xw}{{m}_{i - 1} {m}_{i + 1}}$$
is even, the value of the residue rᵢ is unchanged.

6. The k-cluster residue number system of claim 1, wherein the processor comprises an overflow detection circuit configured to detect overflow when the processor adds two integers X and Y, the overflow detection circuit comprises:
an adder having two inputs for receiving the two integers X and Y, and an output for outputting a sum of the two integers X and Y;
an XNOR gate having two inputs for receiving a sign of the integer X and a sign of the integer Y;
an XOR gate having two inputs for receiving the sign of the integer X and a sign of the sum of the two integers X and Y;
an AND gate having a first input coupled to an output of the XNOR gate, a second input coupled to an output of the XOR gate, and an output for outputting an enable signal;
an overflow correction unit for changing the sign of the sum of the two integers X and Y when the enable signal has a predetermined value;
an inverter having an input for receiving the sign of the sum of the two integers X and Y; and
an overflow accumulator having a first input for receiving the enable signal, a second input coupled to an output of the inverter, and a third input coupled to an output of the overflow accumulator.

7. The k-cluster residue number system of claim 6, wherein the processor corrects a final convolution result according to a signal outputted from the output of the overflow accumulator.

8. The k-cluster residue number system of claim 1, wherein the processor comprises a division circuit for dividing a dividend by a divisor to output a remainder and a quotient, the division circuit comprising:
a quotient factor generator having a first input for receiving a dividend, a second input for receiving a divisor, and an output for outputting a quotient factor according to a cluster index of the dividend and a cluster index of the divisor;
a multiplier having a first input coupled to the output of the quotient factor generator for receiving the quotient factor, a second input for receiving the divisor, and an output for outputting a product of the quotient factor and the divisor;
a subtractor having a first input for receiving the dividend, a second input for receiving the product of the quotient factor and the divisor, and an output for outputting a difference between the dividend and the product of the quotient factor and the divisor;
a sign detector having an input coupled to the output of the subtractor for receiving the difference, a first output, and a second output;
a dividend register having a first input coupled to the output of the subtractor for receiving the difference, a second input coupled to the first output of the sign detector for receiving a sign of the difference, and an output for outputting the difference as an updated dividend if the difference is zero or positive;
an adder having a first input coupled to the output of the quotient factor generator for receiving the quotient factor, a second input for receiving a temporary quotient, and an output for outputting a sum of the quotient factor and the temporary quotient;
a quotient register having a first input coupled to the output of the adder for receiving the sum of the quotient factor and the temporary quotient as an updated temporary quotient, a second input coupled to the second output of the sign detector for receiving the sign of the difference, an output coupled to the second input of the adder for outputting the updated temporary quotient if the sign of the difference is zero or positive;
an XOR gate having two inputs for receiving a sign of the dividend and a sign of the divisor;
a first multiplexer having two inputs coupled to the dividend register for receiving the updated dividend and an updated dividend bar, and a select terminal coupled to an output of the XOR gate, wherein the first multiplexer selectively outputs one of the updated dividend and the updated dividend bar as the remainder according to a signal outputted from the XOR gate; and
a second multiplexer having two inputs coupled to the quotient register for receiving the updated temporary quotient and an updated temporary quotient bar, and a select terminal for receiving the sign of the dividend, wherein the second multiplexer selectively outputs one of the updated temporary quotient and the updated temporary quotient bar as the quotient according to the sign of the dividend.

9. A method for generating a k-cluster residue number system comprising:
generating a modular set composed of P coprime integers, wherein P is an integer greater than 2, and the P coprime integers include 2;
generating a dynamic range by taking a product of the P coprime integers;
generating quotient indices for all integers in the dynamic range;
generating row indices for all integers in the dynamic range;
generating column indices for all integers in the dynamic range;
generating a look-up table according to the quotient indices, row indices, column indices, and all integers in the dynamic range; and
storing the look-up table in a memory of the k-cluster residue number system.

10. The method of claim 9, further comprises:
multiplying two integers x and w by using the look-up table according to the following equation:
$$\frac{xw}{{m}_{i - 1} {m}_{i + 1}} = {q}_{i - 1} {q}_{i + 1} + ⌈ \frac{{q}_{i - 1} {r}_{i + 1}}{{m}_{i + 1}} + \frac{{q}_{i + 1} {r}_{i - 1}}{{m}_{i - 1}} ⌉$$
where:
mᵢ₋₁ and mᵢ₊₁ are two coprime integers of the modular set;
qᵢ₋₁ is a quotient index of the quotient indices when the integer x is divided by mᵢ₋₁;
rᵢ₋₁ is a row index of the row indices when the integer x is divided by mᵢ₋₁;
qᵢ₊₁ is a quotient index of the quotient indices when the integer w is divided by mᵢ₊₁;
rᵢ₊₁ is a row index of the row indices when the integer w is divided by mᵢ₊₁; and
┌┐ is a rounding function.

11. The method of claim 10, further comprises:
performing multiplication overflow correction according to a value of
$$\frac{xw}{{m}_{i - 1} {m}_{i + 1}} .$$

12. The method of claim 11, wherein when the value of
$$\frac{xw}{{m}_{i - 1} {m}_{i + 1}}$$
is odd, a value of a residue rᵢ is changed; and
wherein when the value of
$$\frac{xw}{{m}_{i - 1} {m}_{i + 1}}$$
is even, the value of the residue rᵢ is unchanged.
